(19) United States
(12) Patent Application Publication
(10) Pub. No.: US 2024/0429048 A1
(43) Pub. Date: Dec. 26, 2024

(54) REDUCED STRAIN AND STOP LAYER FOR Si/SiGe EPI STACKS

(71) Applicant: Applied Materials, Inc., Santa Clara, CA (US)

(72) Inventors: Ruiying HAO, San Jose, CA (US); Thomas KIRSCHENHEITER, Santa Clara, CA (US); Arvind KUMAR, Austin, TX (US); Mahendra PAKALA, Saratoga, CA (US); Roya BAGHI, Santa Clara, CA (US); Balasubramanian PRANATHARTHIHARAN, San Jose, CA (US); Fredrick FISHBURN, Los Gatos, CA (US)

(73) Assignee: Applied Materials, Inc., Santa Clara, CA (US)

(21) Appl. No.: 18/745,485

(22) Filed: Jun. 17, 2024

Related U.S. Application Data
(60) Provisional application No. 63/522,113, filed on Jun. 20, 2023.

(51) Int. Cl. H01L 21/02; H01L 29/165

(52) U.S. Cl. CPC H01L 21/02532; H01L 21/02576; H01L 21/02579; H01L 29/165

(57) ABSTRACT

A semiconductor device and a method for manufacturing thereof. A substrate is provided. At least one silicon layer is formed on top of the substrate. At least one silicon-germanium layer is formed on top of at least one silicon layer. At least one silicon-germanium layer includes at least one n-type dopant. The semiconductor device having at least one silicon layer and at least one silicon-germanium layer is formed.

### CROSS-REFERENCE TO RELATED APPLICATIONS

The present application claims priority to U.S. Provisional Patent No. 63/522,113 to Hao et al., filed Jun. 20, 2023, and entitled “Reduced Strain and Stop Layer for Si/SiGe epi stacks,” and incorporates its disclosure herein by reference in its entirety.

### TECHNICAL FIELD

This disclosure relates generally to semiconductor devices, and in particular, semiconductor devices that employ heteroepitaxial structures and associated processes that are capable of reducing strain that may be induced by a mismatch in lattice elements.

### BACKGROUND

Epitaxial layer growth may refer to a crystal growth and/or deposition of material, whereby new crystalline layers may be formed using predetermined orientations vis-à-vis crystalline seed layer with the deposited film being referred to as an epitaxial layer. Orientations of epitaxial and seed layers may be determining using each material's crystal lattice's orientation. Epitaxial growth processes are used in manufacturing of semiconductors, with semiconductor films being epitaxially grown on substrates. Heteroepitaxial growth involves epitaxial growth of materials that are different from one another. However, during such heteroepitaxial growth processes (e.g., using Si/SiGe films), a strain may be introduced from a mismatch in lattice elements of Si lattice and Ge lattice. A wafer bow may be produced as result. While for thin layer growth, wafer bow may be manageable using various known processes, it is not so for thicker layers, where wafer bow requires bow compensation.

### SUMMARY

In some implementations, the current subject matter relates to a method for manufacturing a semiconductor device. The method may include providing a substrate, forming at least one silicon layer on top of the substrate, forming at least one silicon-germanium layer on top of at least one silicon layer, where at least one silicon-germanium layer may include at least one n-type dopant, and forming the semiconductor device having at least one silicon layer and at least one silicon-germanium layer.

In some implementations, the current subject matter may include one or more of the following optional features. The method may further include stacking a plurality of at least one silicon-germanium layer formed on top of at least one silicon layer. The semiconductor device may include the stacked plurality of at least one silicon-germanium layer formed on top of at least one silicon layer.

In some implementations, a thickness of at least one silicon layer may be greater than a thickness of at least one silicon-germanium layer.

In some implementations, the method may also include forming at least one p-type doped region within at least one silicon layer. At least one p-type doped region may be disposed adjacent at least one silicon-germanium layer. The method may further include stacking a plurality of at least one silicon-germanium layer formed on top of at least one silicon layer. At least one silicon layer may have at least one p-type doped region formed within at least one silicon layer. The semiconductor device may include the stacked plurality of at least one silicon-germanium layer formed on top of at least one silicon layer. One or more silicon-germanium layers in the stacked plurality of at least one silicon-germanium layer formed on top of at least one silicon layer may be configured to be adjacent to one or more p-type doped regions formed within silicon layers adjacent to one or more silicon-germanium layers. One or more p-type doped regions may include one or more p-type dopants. One or more p-type dopants may include at least one of the following: boron, carbon, boron and carbon, and any combination thereof.

In some implementations, the method may also include forming at least one tensile layer on a bottom of at least one silicon layer. Formation of at least one tensile layer may include forming at least one n-type doped silicon layer on top of the substrate, forming at least one p-type stop layer on top of the n-type doped silicon layer, and removing at least a portion of the n-type doped silicon layer. The method may also include removing the substrate and reducing a concentration of germanium in the silicon-germanium layer, thereby reducing a curvature of the substrate.

In some implementations, a thickness of the at least one p-type stop layer may be less than a thickness of at least one n-type doped silicon layer.

In some implementations, the n-type dopant may include at least one of the following: phosphorous, arsenic, antimony, bismuth, lithium, and any combination thereof.

In some implementations, the current subject matter relates to a semiconductor device. The device may include a substrate, at least one silicon layer formed on top of the substrate, at least one silicon-germanium layer formed on top of at least one silicon layer, where at least one silicon-germanium layer may include at least one n-type dopant.

In some implementations, the device may also include a stacked plurality of at least one silicon-germanium layer formed on top of at least one silicon layer. A thickness of at least one silicon layer may be greater than a thickness of at least one silicon-germanium layer. The device may further include at least one p-type doped region formed within the at least one silicon layer, where at least one p-type doped region may be disposed adjacent at least one silicon-germanium layer. In some implementations, the device may include a stacked plurality of at least one silicon-germanium layer formed on top of the at least one silicon layer, where at least one silicon layer may have at least one p-type doped region formed within at least one silicon layer.

In some implementations, in the semiconductor device, one or more silicon-germanium layers in the stacked plurality of at least one silicon-germanium layer formed on top of at least one silicon layer may be adjacent to one or more p-type doped regions formed within silicon layers adjacent to one or more silicon-germanium layers. One or more p-type doped regions may include one or more p-type dopants, the one or more p-type dopants include at least one of the following: boron, carbon, boron and carbon, and any combination thereof.

In some implementations, the semiconductor device may include at least one tensile layer formed on a bottom of at least one silicon layer. At least one tensile layer may be formed by forming at least one n-type doped silicon layer on top of the substrate, forming at least one p-type stop layer on top of the n-type doped silicon layer, and removing at least a portion of the n-type doped silicon layer.

In some implementations, in the semiconductor device, a thickness of at least one p-type stop layer may be less than a thickness of at least one n-type doped silicon layer. The n-type dopant may include at least one of the following: phosphorous, arsenic, antimony, bismuth, lithium, and any combination thereof.

The details of one or more variations of the subject matter described herein are set forth in the accompanying drawings and the description below. Other features and advantages of the subject matter described herein will be apparent from the description and drawings, and from the claims.

### BRIEF DESCRIPTION OF THE DRAWINGS

The accompanying drawings, which are incorporated in and constitute a part of this specification, show certain aspects of the subject matter disclosed herein and, together with the description, help explain some of the principles associated with the disclosed implementations. The drawings are schematic in nature and do not represent actual dimensions or aspect ratios. In the drawings,

FIGS. 1a-c illustrate example semiconductor devices, respectively, according to some implementations of the current subject matter;

FIGS. 2a-b illustrate example structures used during a formation of a tensile layer for including in one or more semiconductor devices shown in FIGS. 1a-c, respectively, according to some implementations of the current subject matter.

FIG. 3 illustrates an example process 300 for forming a tensile layer, according to some implementations of the current subject matter; and

FIG. 4 illustrates an example process, according to some implementations of the current subject matter.

### DETAILED DESCRIPTION

To address these and potentially other deficiencies of currently available solutions, one or more implementations of the current subject matter relate to methods, systems, articles of manufacture, and the like that can, among other possible advantages, provide semiconductor devices that use heteroepitaxial structures and associated processes that may be capable of reducing strain that may be induced by a mismatch in one or more lattice elements.

In some implementations, the current subject matter relates to an ability to compensate and/or reduce wafer bow in semiconductor devices that have been heteroepitaxially grown, such as, for the purposes of producing a dynamic random-access memory (DRAM) device. A typical DRAM device may include alternating layers of silicon (Si) and silicon-germanium (SiGe) that may be epitaxially grown from a crystal silicon substrate. A mismatch may occur in the lattice between Si and Ge, which may cause a strain causing wafer bow. As stated above, in thin layers, such wafer bow is less problematic than in thick layers. To solve this issue, the current subject matter's compensation and/or reduction may be performed either during one or more the stages of the heteroepitaxial growth process and/or after completion of one or more stages and/or the entire growth process. The compensation may be performed through one or more of the following ways: addition of n-type dopant in the SiGe layer, addition of carbon and/or carbon-boron on either side of SiGe layer that is to be selectively etched, and/or adding a tensile Si layer(s) to frontside before memory stack epi processing. Each of these will be discussed in further detail below.

Addition of an n-type dopant to the SiGe layer may be helpful during selective removal of the SiGe layer. Moreover, it may cause reduction of Ge concentration in the SiGe layer, which may have further benefits in reducing wafer bow. By way of a non-limiting example, an n-type dopant may be phosphorous with a smaller lattice constant. Thus, the combination of the added phosphorous and resulting decrease in concentration of Ge in the SiGe layer may help with bow reduction in the wafer. As can be understood, any other n-dopant materials may be used.

Addition of carbon and/or a combination of carbon and boron on one or both sides of the SiGe layer being selectively etched may be configured to cause a reduction in the etch rate of Si that may be exposed during the selective etching process. In particular, use of carbon and/or a carbon-boron combination may be helpful in increasing the SiGe layer etching while decreasing Si layer etching. This in turn, may also assist with compensation of the wafer bow. Carbon's smaller lattice constant (e.g., smaller than silicon's lattice constant) may be used to offset any lattice mismatch with germanium that has a larger lattice constant. For example, germanium's lattice constant is approximately 1.04 times silicon's lattice constant, while carbon's lattice constant is 0.66 times silicon's lattice constant. For instance, in a layer stack, carbon may be added to the silicon layer, thereby producing a SiC layer. The silicon layer receiving carbon may, for example, be approximately 15 nanometer (nm) thick, and the added carbon may have a 0.5% concentration. Addition of carbon to the silicon layers may be performed on one or both sides of silicon germanium layer doped with n-dopant (e.g., phosphorous (SiGe-Phos)), which is sandwiched between the silicon layers in the stack. The SiGe-Phos layer may, for example, have a 10 nm thickness and 13% concentration of germanium. The resulting combination may be configured to substantially fully compensate stress from presence of germanium, and hence, reduce wafer bow. Further, as indicated above, instead of carbon, boron and/or carbon-boron combination may be added to the silicon layers surrounding the SiGe-Phos layers. A concentration of the added elements may be selected based on a desired degree of reduction of wafer bow, as well as, for example, specific design specification of any final products, layer thicknesses, layer arrangement, etc. As can be understood, the above numerical examples are provided herein for illustration purposes only and are not intended to limit the scope of the subject matter described herein.

Alternatively, or in addition, one or more tensile silicon layer(s) may be added to the frontside before the memory stack epi processing. The tensile silicon layer(s) may be doped with carbon, boron, phosphorous and/or any combination thereof, and have sufficient thickness to not only provide sufficient compensation but also prevent crystal defects from relaxation. In one example, non-limiting implementation, a thick phosphorous-doped silicon epi layer may be followed by a thin boron doped epi, which may be helpful during backside silicon removal process at a later stage.

It should be noted that, when used herein, a substrate may refer to any substrate and/or material surface formed on a substrate upon which film processing may be performed during a fabrication process. A substrate material may, for example, include, but is not limited to, silicon, silicon oxide, strained silicon, silicon on insulator (SOI), carbon doped silicon oxides, amorphous silicon, doped silicon, germanium, gallium arsenide, glass, sapphire, and/or any other materials, such as, for instance, metals, metal nitrides, metal alloys, and/or any other conductive materials, etc. (which may be specific to a particular implementation, application, use, etc.) Substrates may also include semiconductor wafers. Substrates may be exposed to one or more pretreatment processes, such as, for example, to polish, etch, reduce, oxidize, hydroxylate, anneal, UV cure, e-beam cure and/or bake the substrate surface. The substrate surface and/or substrate may include an underlayer, such as, for instance, upon depositing a film/layer and/or partial film/layer onto a substrate surface, an exposed surface of the deposited film/layer becomes the substrate surface.

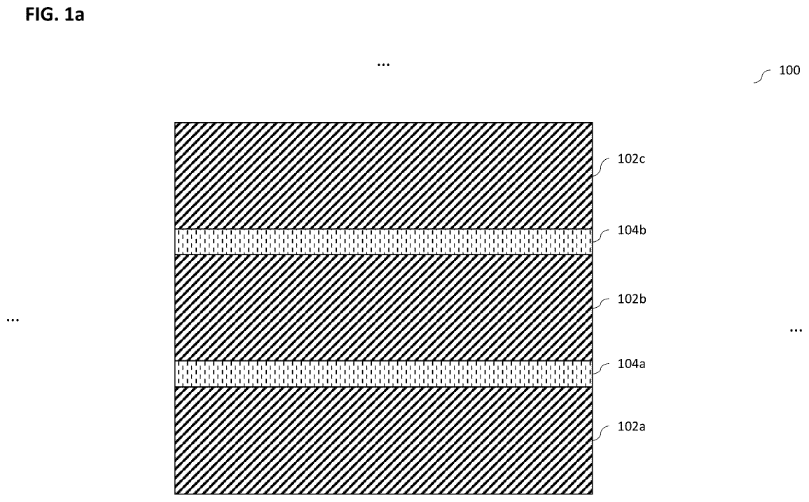

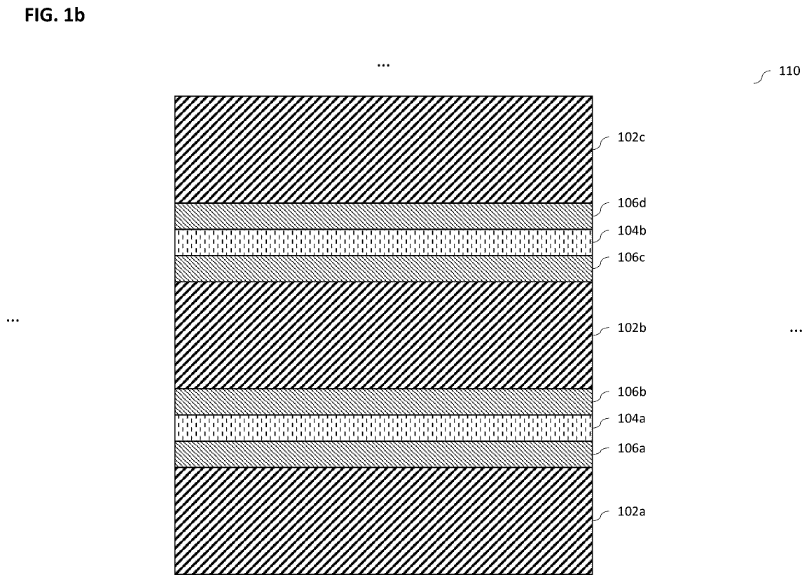

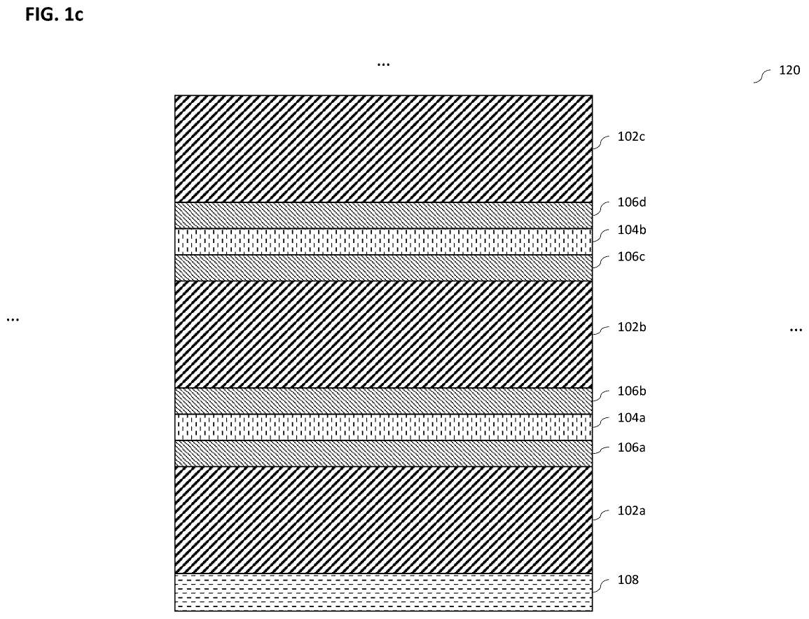

FIGS. 1a-c illustrate example semiconductor devices 100-120, respectively, according to some implementations of the current subject matter. The devices 100-120 may be used for forming of dynamic random-access memory (DRAM) devices, and/or any other type of memory devices. The devices 100-120 may be configured to include a plurality of stacked layers and/or groups of layers that may be disposed directly on top of one another and/or side-by-side. For ease of illustration, FIGS. 1a-c show only a limited number of such layers. As can be understood, any number of layers may be stacked directly on top of one another. As used herein, the term “on”, as used with respect to a film and/or a layer of a film, may include the film and/or layer being directly disposed on a surface, and/or on one or more underlayers between the film and/or layer and the surface.

A layer may refer to a single crystalline layer of material and/or multiple crystalline layers of the same material, which, may, upon being combined, form a single crystalline layer. The devices 100-120 may, for example, include a plurality of alternating silicon (Si) and silicon germanium (SiGe) layer, where thickness or height of each Si layer may be greater than thickness or height of SiGe layer. Alternatively, or in addition, at least one Si layer may have thickness or height that may be less than thickness or height of at least on SiGe layer. As can be understood, any combination of thicknesses/heights of layers is possible.

Further, as described herein, one or more SiGe and/or Si layers of the devices 100-120 may be doped with and/or include at least one dopant. Some non-limiting examples of dopants may include carbon, boron, phosphorous, oxygen, nitrogen, and/or any other types of dopants, and/or any combinations thereof. Moreover, the devices 100-120 may be configured to include any combination of doped and non-doped Si layers and/or doped SiGe layers. For example, a doped Si layer may be disposed adjacent and/or at each side of a doped and/or non-doped SiGe layer. Alternatively, or in addition, a doped SiGe layer may be disposed adjacent and/or at each side of a doped and/or non-doped Si layer. Each doped and/or non-doped layer may have a respective thickness and/or height that may be selected in accordance with design requirements and/or characteristics for the devices 100-120. Further, each doped layer may have specific desired doping concentrations (for instance, of one or more dopants), which may again be selected in accordance with particular requirements/characteristics of the devices 100-120. The doping concentration may be configured to be uniform throughout the entire stack of layers. Alternatively, or in addition, the doping concentration may be non-uniform and may vary from doped layer to doped layer in the stack, e.g., the doping concentration may vary from a bottom doped layer in the stack to the top layer in the stack (if so desired). Such non-uniform doping may assist in formation of uniform recess of SiGe layers (depending on recess etch conditions).

Referring to FIG. 1a, the device 100 may include silicon layers 102a, 102b, 102c and one or more silicon germanium layers 104a, 104b that may be doped with an n-dopant. As stated above, any number of silicon layers 102 and silicon germanium layers 104 may be used. The silicon germanium layers 104 may be configured to alternate with the silicon layers 102. For example, the silicon germanium layer 104a may be disposed between the silicon layer 102a and silicon layer 102b, where the silicon germanium layer 104a may be disposed on top of the silicon layer 102a and the silicon layer 102b may be disposed on top of the silicon germanium layer 104a. Similarly, silicon germanium layer 104b may be disposed between the silicon layer 102b and silicon layer 102c, where the silicon germanium layer 104b may be disposed on top of the silicon layer 102b and the silicon layer 102c may be disposed on top of the silicon germanium layer 104b.

As shown in FIG. 1a, the thicknesses or heights of the silicon layers 102 may be greater than the thicknesses or heights of silicon germanium layers 104. Alternatively, or in addition, thickness/height of at least one silicon germanium layer 104 may be greater than thickness/height at least one silicon layer 102. Further, while FIG. 1a, illustrates uniform thickness/height for each silicon layer 102 and similarly, for each silicon germanium layer 104, it may be understood that the thicknesses/heights of such respective layers 102, 104 might not be uniform. For example, thickness/height of layer 102a may be greater than thickness/height of layer 102b, etc. (similarly, for layers 104). Disposition or growth of each respective layer 102 and 104 may be performed in accordance with any existing techniques.

In some implementations, for the purposes of reducing wafer bow as well as to enhance selective etch process, one or more of the silicon germanium layers 104 may be doped with a dopant, such as, for example, an n-dopant. It should be noted that SiGe layers are typically selectively etched compared to Si layers. As such, addition of n-type dopants to the SiGe layers may be configured to increase availability of electrons, thereby improving the etch rate of the SiGe layers. Enhancement in the etch rate may cause further reduction of concentration of germanium in the SiGe layers, thereby reducing an impact of the SiGe layers on wafer bow.

In some example, non-limiting implementations, concentration of the n-type dopant may be approximately less than or equal to 0.01%. The concentration of the n-type dopant may be selected based on a specific dopant and desired strain reduction effect. For instance, higher doping levels of phosphorous dopant having a smaller lattice constant (as compared to silicon) may be effective in lowering strain. By contrast, use of arsenic and/or antimony dopants may lead to less diffusivity and increase in strain because each has a larger lattice constant (as compared to silicon). As can be understood, any type of n-type dopant may be used, where examples of such n-type dopants may include, but are not limited to, phosphorous, arsenic, antimony, bismuth, lithium, and/or any other n-type dopant, and/or any combination thereof. As stated above, the doping of layers may be uniform and/or non-uniform (e.g., varying) in the stack.

FIG. 1b illustrates an example device 110 that may include one or more regions that may be doped with a p-type dopant to further improve selective etching process and reduce bow compensation, according to some implementations of the current subject matter. In a non-limiting implementation, addition of a p-type dopant and/or carbon to the silicon layer disposed next to the silicon germanium layer may be configured to reduce the silicon layer etch rate, which, in turn, may be helpful in removal SiGe layer with respect to the silicon layer loss. Use of carbon and absence of electrons in the silicon layer may be configured to decrease the etch rate of the silicon layer. This may be configured to permit a more aggressive SiGe layer etch process, during which higher etch rate may be used causing reduction of germanium concentration in the SiGe layer, thereby reducing the impact of the SiGe layer on wafer bow. While the created p-type and/or carbon doped silicon layer might not be advantageous to the DRAM device channel, this layer's thickness may be kept within the thickness of silicon layer that may be later removed when silicon is thinned to form the final thickness of silicon for the semiconductor device (e.g., a transistor). Moreover, a graded and/or thin silicon transition layer may be added to buffer the transition in the epi layer from a compressive to tensile film, which may help reduce the formation of crystal defects.

As shown in FIG. 1b, the device 110, similar to device 100 shown in FIG. 1a, may include silicon layers 102a, 102b, 102c and one or more silicon germanium layers 104a, 104b that may be doped with an n-dopant. Again, any number of silicon layers 102 and silicon germanium layers 104 may be used. The silicon germanium layers 104 may be configured to alternate with the silicon layers 102.

In addition to the layers 102 and 104, one or more silicon layers 102 may be configured to include one or more doped regions 106 (a, b, c, d). The regions 106 may be doped with a p-type dopant. Such p-type dopant may include, but is not limited to, carbon, boron, carbon and boron, and/or any other p-type dopant, and/or any combination thereof. For example, the silicon layer 102a may be configured to include a doped region 106a, silicon layer 102b may be configured to include doped regions 106b and 106c, and silicon layer 102c may include a doped region 106d. As can be understood, silicon layers 102 may include any number of doped regions 106.

Further, the doped regions 106 may be disposed within the respective silicon layers 102 and adjacent each side of respective n-type doped layers 104. For example, the doped region 106a, disposed within the silicon layer 102a, may be disposed adjacent a bottom of the silicon germanium layer 104a; the doped region 106b, disposed within the silicon layer 102b, may be disposed adjacent a top of the silicon germanium layer 104a; the doped region 106c, disposed within the silicon layer 102b, may be disposed adjacent a bottom of the silicon germanium layer 104b; and the doped region 106d, disposed within the silicon layer 102c, may be disposed adjacent a top of the silicon germanium layer 104b. Thickness, height, and/or concentration of each doped region 106 may be determined in accordance with specific characteristics of the device 110, one or more indented uses and/or particular applications of the device 110. For example, thickness and/or height of layers 104 may be comparable to the thickness and/or height of regions 106. Alternatively, or in addition, each region 106 may have same or different thickness and/or height as another region 106 and/or one or more layers 104.

FIG. 1c illustrates an example device 120 that may incorporate the layers and regions of one or more devices 100 and 110, as shown in FIGS. 1a and 1b, respectively, as well as include an additional tensile layer disposed on the frontside of the device, according to some implementations of the current subject matter. As shown in FIG. 1c, the device 120 may, similar to the 100 and device 110, shown in FIGS. 1a-b, may include silicon layers 102 having one or more n-type doped regions 106, and one or more silicon germanium layers 104 doped with an n-dopant. Again, any number of silicon layers 102 and silicon germanium layers 104 may be used. The silicon germanium layers 104 may be configured to alternate with the silicon layers 102.

In addition to the layers 102 and 104, a tensile layer 108 may be added to the frontside of the device 120 and adjacent, for example, silicon layer 102a. The layer 108 may be added before memory stack processing. The layer 108 may be a silicon layer doped with a p-dopant, such as for example, boron. Alternatively, or in addition, the layer 108 may be a combination of one or more layers, bi-layers, and/or any other types of layers. For example, the layer 108 may include a combination of layers such as, a thick n-type doped (e.g., phosphorous-doped) silicon layer followed by a thin p-type doped (e.g., boron) silicon layer. The layer 108 may be further configured to aid in backside silicon removal process. Moreover, as discussed herein, the layer doping may be uniform and/or non-unform among layers in the stack.

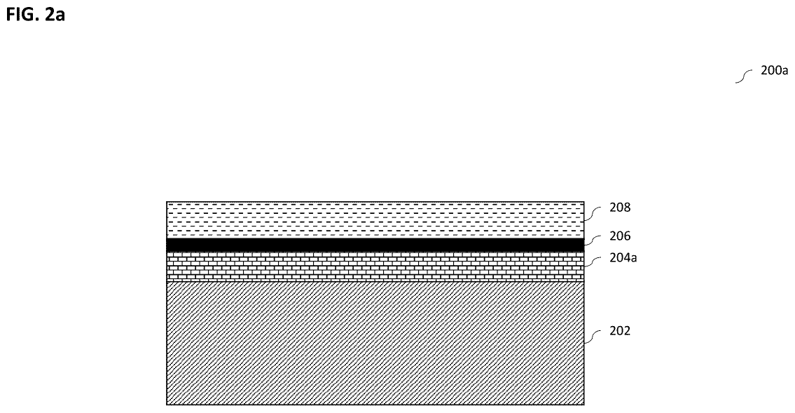

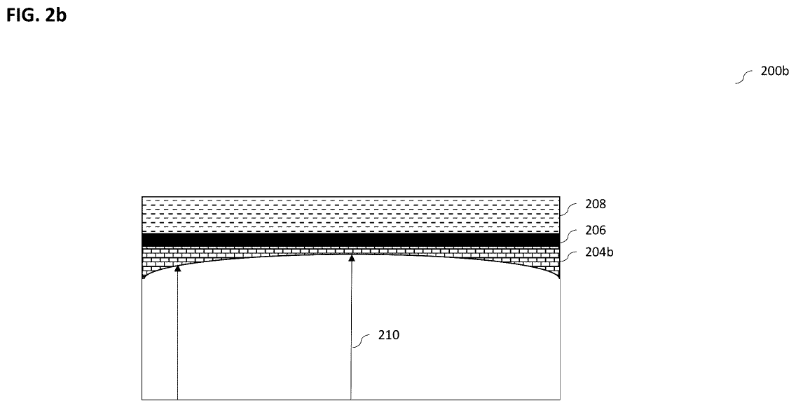

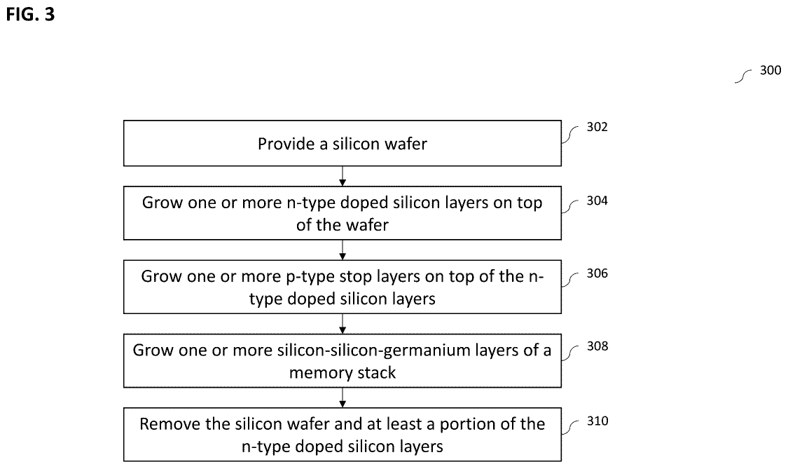

FIGS. 2a-b illustrate example structures 200 (a, b) used during a formation of a tensile layer for including in one or more devices 100-120 shown in FIGS. 1a-c, respectively, according to some implementations of the current subject matter. FIG. 3 illustrates an example process 300 for forming a tensile layer, according to some implementations of the current subject matter.

Referring to FIGS. 2a-b and 3, the process of forming a tensile layer may be initiated by providing a silicon wafer 202, at 302. In some example, non-limiting implementations, the silicon wafer 202 may be approximately 750 micrometers (um) thick. By way of a background, after memory cell processing is complete on the front side of the wafer it is often the case that the backside silicon may need to be removed to access the memory cell from the backside. Typically, this may involve removal of more than 750 μm of silicon to a very small thickness (e.g., less than 0.1 um) of silicon remaining before the memory cell array. Such removal may be aided through addition of a thin p-type wet etch stop layer above a thick n-type silicon wet etch layer. The backside polish of silicon may be stopped within the n-type region. Then, wet silicon etch may be used to easily remove the n-type silicon and stop etching on the thin p-type silicon. The thin stop layer may be uniformly removed using conventional etch processes.

At 304 (as shown in FIG. 3), a n-type doped silicon layer 204a may be grown on top of the silicon wafer 202, as shown in FIG. 2a. The n-type (e.g., N+) doped silicon layer 204a may be configured to have a thickness of 10-20 um. The dopant may be phosphorous and/or any other type of dopant material.

At 306 (as shown in FIG. 3), a stop layer 206 may be formed on top of the doped silicon layer 204a. The stop layer 206 may have a thickness than may be less and/or substantially less than the thickness of the doped silicon layer 204a. The stop layer may be p-type (P+) doped. The dopant may be boron and/or any other type of dopant material.

At 308, one or more silicon-silicon-germanium layers combinations 208 (e.g., memory stack) may be formed on top of the stop layer 206. The layers combinations 208 may be similar to the combinations of layers 102 (whether or not including regions 106) and/or 104, as shown in one or more of FIGS. 1a-c. Formation of the memory stack (i.e., layers combinations 208) may complete the device 202a shown in FIG. 2a.

At 310 (as shown in FIG. 3), to complete the formation of a memory device, a removal 210 of the silicon wafer 202 and at least a portion of the n-type doped layer 204a may be performed. Removal of at least a portion the n-type doped layer 204a results in the formation of the n-type doped layer 204b, as shown in FIG. 2b. Removal of the silicon wafer and portion of the layer 204a may be accomplished through any known processes, such as, for example back grinding. The removal 210 may be configured to stop once and/or before it reaches the thin p-type stop layer 206. The resulting n-type doped layer 204b may have any desired shape, such as for example, an arcuate shape shown in FIG. 2b. As can be understood, any desired shape of the layer 204b may be achieved and used in the device 202b.

Further, in some implementations, the remaining stop layer 206 and the layer 204b may be used to reduce bow of the silicon-germanium layer before any silicon-silicon-germanium layers may be formed. As can be understood, the stop layer 206 may also be removed using any conventional etch processes.

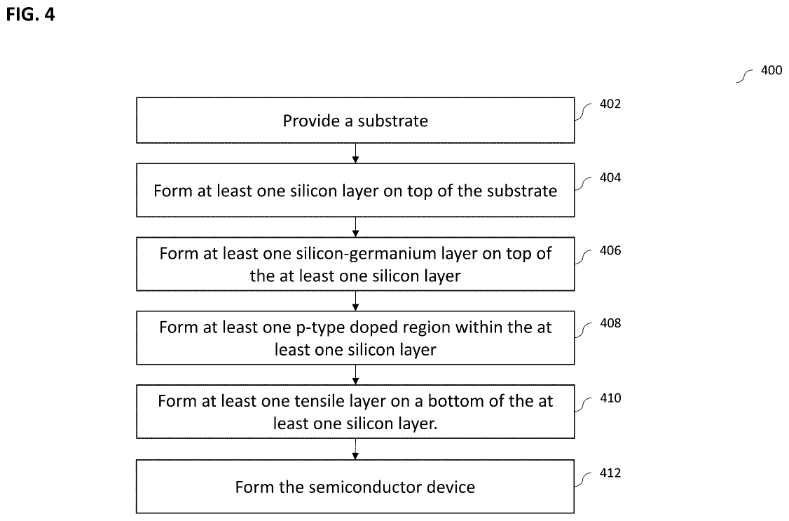

FIG. 4 illustrates an example process 400 for manufacturing a semiconductor device, according to some implementations of the current subject matter. The process 400 may include any of the components and/or operations discussed herein with regard to FIGS. 1a-3. At 402, a substrate may be provided (e.g., substrate or silicon wafer 202). At 404, at least one silicon layer may be formed on top of the substrate. At 406, at least one silicon-germanium layer may be formed on top of the silicon layer. The one silicon-germanium layer may include at least one n-type dopant.

At 408, at least one p-type doped region may be formed within the silicon layer. The p-type doped region may be disposed adjacent the silicon-germanium layer. At 412, at least one tensile layer may be formed on a bottom of the silicon layer. At 414, the semiconductor device having one or more of the above layers may be formed.

In some implementations, the current subject matter may have one or more of the following optional features. For example, the process 400 may include stacking a plurality of the silicon-germanium layers formed on top of silicon layers, where the semiconductor device may include the stacked plurality of one or more silicon-germanium layer formed on top of one or more silicon layers.

In some implementations, a thickness of at least one silicon layer may be greater than a thickness of at least one silicon-germanium layer.

In some implementations, the process 400 may include stacking a plurality of silicon-germanium layers formed on top of silicon layers, where the silicon layers may have at least one p-type doped region formed within. Further, one or more silicon-germanium layers in the stacked plurality of the at least one silicon-germanium layer formed on top of the at least one silicon layer is configured to be adjacent to one or more p-type doped regions formed within silicon layers adjacent to the one or more silicon-germanium layers. One or more p-type doped regions may include one or more p-type dopants. One or more p-type dopants may include at least one of the following: boron, carbon, boron and carbon, and any combination thereof.

In some implementations, formation of the tensile layer may include forming at least one n-type doped silicon layer on top of the substrate, forming at least one p-type stop layer on top of the n-type doped silicon layer, and removing at least a portion of the n-type doped silicon layer. In some implementations, the process 400 may also include removal of the substrate and reducing a concentration of germanium in the silicon-germanium layer, thereby reducing a curvature of the substrate (e.g., wafer bow).

In some implementations, a thickness of at least one p-type stop layer is less than a thickness of at least one n-type doped silicon layer. The n-type dopant may include at least one of the following: phosphorous, arsenic, antimony, bismuth, lithium, and any combination thereof.

It will be appreciated that the exemplary devices shown in the block diagrams described above may represent one functionally descriptive example of many potential implementations. Accordingly, division, omission or inclusion of block functions depicted in the accompanying figures does not infer that the hardware components, circuits, software and/or elements for implementing these functions would necessarily be divided, omitted, or included in implementations.

Some implementations may be described using the expression “one implementation” or “an implementation” along with their derivatives. These terms mean that a particular feature, structure, or characteristic described in connection with the implementation is included in at least one implementation. The appearances of the phrase “in one implementation” in various places in the specification are not necessarily all referring to the same implementation. Moreover, unless otherwise noted the features described above are recognized to be usable together in any combination. Thus, any features discussed separately may be employed in combination with each other unless it is noted that the features are incompatible with each other.

In one aspect, a method for manufacturing a semiconductor device may include providing a substrate; forming at least one silicon layer on top of the substrate; forming at least one silicon-germanium layer on top of the at least one silicon layer, the at least one silicon-germanium layer including at least one n-type dopant; and forming the semiconductor device having the at least one silicon layer and the at least one silicon-germanium layer.

The method may also include stacking a plurality of the at least one silicon-germanium layer formed on top of the at least one silicon layer, the semiconductor device including the stacked plurality of the at least one silicon-germanium layer formed on top of the at least one silicon layer.

The method may also include wherein a thickness of the at least one silicon layer is greater than a thickness of the at least one silicon-germanium layer.

The method may also include forming at least one p-type doped region within the at least one silicon layer, the at least one p-type doped region being disposed adjacent the at least one silicon-germanium layer.

The method may also include stacking a plurality of the at least one silicon-germanium layer formed on top of the at least one silicon layer, the at least one silicon layer having the at least one p-type doped region formed within the at least one silicon layer; the semiconductor device including the stacked plurality of the at least one silicon-germanium layer formed on top of the at least one silicon layer.

The method may also include wherein one or more silicon-germanium layers in the stacked plurality of the at least one silicon-germanium layer formed on top of the at least one silicon layer is configured to be adjacent to one or more p-type doped regions formed within silicon layers adjacent to the one or more silicon-germanium layers.

The method may also include wherein the one or more p-type doped regions include one or more p-type dopants, the one or more p-type dopants include at least one of the following: boron, carbon, boron and carbon, and any combination thereof.

The method may also include forming at least one tensile layer on a bottom of the at least one silicon layer.

The method may also include wherein the forming the at least one tensile layer includes forming at least one n-type doped silicon layer on top of the substrate; forming at least one p-type stop layer on top of the n-type doped silicon layer; and removing at least a portion of the n-type doped silicon layer.

The method may also include removing the substrate.

The method may also include reducing a concentration of germanium in the silicon-germanium layer, thereby reducing a curvature of the substrate.

The method may also include wherein a thickness of the at least one p-type stop layer is less than a thickness of the at least one n-type doped silicon layer.

The method may also include wherein the n-type dopant includes at least one of the following: phosphorous, arsenic, antimony, bismuth, lithium, and any combination thereof.

In one aspect, a semiconductor device may include a substrate; at least one silicon layer formed on top of the substrate; and at least one silicon-germanium layer formed on top of the at least one silicon layer, the at least one silicon-germanium layer including at least one n-type dopant.

The semiconductor device may also include a stacked plurality of the at least one silicon-germanium layer formed on top of the at least one silicon layer.

The semiconductor device may also include wherein a thickness of the at least one silicon layer is greater than a thickness of the at least one silicon-germanium layer.

The semiconductor device may also include at least one p-type doped region formed within the at least one silicon layer, the at least one p-type doped region being disposed adjacent the at least one silicon-germanium layer.

The semiconductor device may also include a stacked plurality of the at least one silicon-germanium layer formed on top of the at least one silicon layer, the at least one silicon layer having the at least one p-type doped region formed within the at least one silicon layer.

The semiconductor device may also include wherein one or more silicon-germanium layers in the stacked plurality of the at least one silicon-germanium layer formed on top of the at least one silicon layer is configured to be adjacent to one or more p-type doped regions formed within silicon layers adjacent to the one or more silicon-germanium layers.

The semiconductor device may also include wherein the one or more p-type doped regions include one or more p-type dopants, the one or more p-type dopants include at least one of the following: boron, carbon, boron and carbon, and any combination thereof.

The semiconductor device may also include at least one tensile layer formed on a bottom of the at least one silicon layer.

The semiconductor device may also include wherein the at least one tensile layer is formed by forming at least one n-type doped silicon layer on top of the substrate; forming at least one p-type stop layer on top of the n-type doped silicon layer; and removing at least a portion of the n-type doped silicon layer.

The semiconductor device may also include wherein a thickness of the at least one p-type stop layer is less than a thickness of the at least one n-type doped silicon layer.

The semiconductor device may also include wherein the n-type dopant includes at least one of the following: phosphorous, arsenic, antimony, bismuth, lithium, and any combination thereof.

It is emphasized that the abstract of the disclosure is provided to allow a reader to quickly ascertain the nature of the technical disclosure. It is submitted with the understanding that it will not be used to interpret or limit the scope or meaning of the claims. In addition, in the foregoing detailed description, it can be seen that various features are grouped together in a single implementation for the purpose of streamlining the disclosure. This method of disclosure is not to be interpreted as reflecting an intention that the claimed implementations require more features than are expressly recited in each claim. Rather, as the following claims reflect, inventive subject matter lies in less than all features of a single disclosed implementation. Thus, the following claims are hereby incorporated into the detailed description, with each claim standing on its own as a separate implementation. In the appended claims, the terms “including” and “in which” are used as the plain-English equivalents of the respective terms “comprising” and “wherein,” respectively. Moreover, the terms “first,” “second,” “third,” and so forth, are used merely as labels, and are not intended to impose numerical requirements on their objects.

What has been described above includes examples of the disclosed architecture. It is, of course, not possible to describe every conceivable combination of components and/or methodologies, but one of ordinary skill in the art may recognize that many further combinations and permutations are possible. Accordingly, the novel architecture is intended to embrace all such alterations, modifications and variations that fall within the spirit and scope of the appended claims.

The foregoing description of example implementations has been presented for the purposes of illustration and description. It is not intended to be exhaustive or to limit the present disclosure to the precise forms disclosed. Many modifications and variations are possible in light of this disclosure. It is intended that the scope of the present disclosure be limited not by this detailed description, but rather by the claims appended hereto. Future filed applications claiming priority to this application may claim the disclosed subject matter in a different manner and may generally include any set of one or more limitations as variously disclosed or otherwise demonstrated herein.

What is claimed:

1. A method for manufacturing a semiconductor device, comprising:
providing a substrate;
forming at least one silicon layer on top of the substrate;
forming at least one silicon-germanium layer on top of the at least one silicon layer, the at least one silicon-germanium layer including at least one n-type dopant; and
forming the semiconductor device having the at least one silicon layer and the at least one silicon-germanium layer.

2. The method according to claim 1, further comprising stacking a plurality of the at least one silicon-germanium layer formed on top of the at least one silicon layer, the semiconductor device including the stacked plurality of the at least one silicon-germanium layer formed on top of the at least one silicon layer.

3. The method according to claim 1, wherein a thickness of the at least one silicon layer is greater than a thickness of the at least one silicon-germanium layer.

4. The method according to claim 1, further comprising forming at least one p-type doped region within the at least one silicon layer, the at least one p-type doped region being disposed adjacent the at least one silicon-germanium layer.

5. The method according to claim 4, further comprising stacking a plurality of the at least one silicon-germanium layer formed on top of the at least one silicon layer, the at least one silicon layer having the at least one p-type doped region formed within the at least one silicon layer;
the semiconductor device including the stacked plurality of the at least one silicon-germanium layer formed on top of the at least one silicon layer.

6. The method according to claim 5, wherein one or more silicon-germanium layers in the stacked plurality of the at least one silicon-germanium layer formed on top of the at least one silicon layer is configured to be adjacent to one or more p-type doped regions formed within silicon layers adjacent to the one or more silicon-germanium layers.

7. The method according to claim 6, wherein the one or more p-type doped regions include one or more p-type dopants, the one or more p-type dopants include at least one of the following: boron, carbon, boron and carbon, and any combination thereof.

8. The method according to claim 4, further comprising forming at least one tensile layer on a bottom of the at least one silicon layer.

9. The method according to claim 8, wherein the forming the at least one tensile layer includes
forming at least one n-type doped silicon layer on top of the substrate;
forming at least one p-type stop layer on top of the n-type doped silicon layer; and
removing at least a portion of the n-type doped silicon layer.

10. The method according to claim 9, further comprising removing the substrate.

11. The method according to claim 10, further comprising reducing a concentration of germanium in the silicon-germanium layer, thereby reducing a curvature of the substrate.

12. The method according to claim 9, wherein a thickness of the at least one p-type stop layer is less than a thickness of the at least one n-type doped silicon layer.

13. The method according to claim 1, wherein the n-type dopant includes at least one of the following: phosphorous, arsenic, antimony, bismuth, lithium, and any combination thereof.

14. A semiconductor device, comprising:
a substrate;
at least one silicon layer formed on top of the substrate; and
at least one silicon-germanium layer formed on top of the at least one silicon layer, the at least one silicon-germanium layer including at least one n-type dopant.

15. The semiconductor device according to claim 14, further comprising a stacked plurality of the at least one silicon-germanium layer formed on top of the at least one silicon layer.

16. The semiconductor device according to claim 14, wherein a thickness of the at least one silicon layer is greater than a thickness of the at least one silicon-germanium layer.

17. The semiconductor device according to claim 14, further comprising at least one p-type doped region formed within the at least one silicon layer, the at least one p-type doped region being disposed adjacent the at least one silicon-germanium layer.

18. The semiconductor device according to claim 17, further comprising a stacked plurality of the at least one silicon-germanium layer formed on top of the at least one silicon layer, the at least one silicon layer having the at least one p-type doped region formed within the at least one silicon layer;
wherein one or more silicon-germanium layers in the stacked plurality of the at least one silicon-germanium layer formed on top of the at least one silicon layer is configured to be adjacent to one or more p-type doped regions formed within silicon layers adjacent to the one or more silicon-germanium layers.

19. The semiconductor device according to claim 18, wherein the one or more p-type doped regions include one or more p-type dopants, the one or more p-type dopants include at least one of the following: boron, carbon, boron and carbon, and any combination thereof.

20. The semiconductor device according to claim 17, further comprising at least one tensile layer formed on a bottom of the at least one silicon layer;
wherein the at least one tensile layer is formed by
forming at least one n-type doped silicon layer on top of the substrate;
forming at least one p-type stop layer on top of the n-type doped silicon layer; and
removing at least a portion of the n-type doped silicon layer.
